(19) United States
(12) Patent Application Publication
(10) Pub. No.: US 2015/0282360 A1
(43) Pub. Date: Oct. 1, 2015

(54) LIGHT GUIDE MEMBER AND ELECTRONIC DEVICE USING SAME

(71) Applicant: HON HAI PRECISION INDUSTRY CO., LTD., New Taipei (TW)

(72) Inventors: JEN-HUI OH, New Taipei (TW); CHING-HUA TSAI, New Taipei (TW); CHUNG-YU LEE, New Taipei (TW)

(21) Appl. No.: 14/670,745

(22) Filed: Mar. 27, 2015

(30) Foreign Application Priority Data
Mar. 31, 2014 (TW) 103111982

(51) Int. Cl. H05K 5/03; G02B 6/10; G02B 6/36; H05K 5/00

(52) U.S. Cl. CPC H05K 5/03; H05K 5/0017; G02B 6/10; G02B 6/3628

(57) ABSTRACT

A device using both an indicator and a light signal receiver includes a cover, a display panel fixed on the cover, and a light guide member to fix and receive a light receiver. A first through hole is defined in the cover. The light guide member includes a main body and two fixing members arranged on the opposite sides of the main body; the two fixing members latch in the first through hole to fix the light guide member on the cover instead of the light guide member being made integral with the cover.

### CROSS-REFERENCE TO RELATED APPLICATIONS

This application claims priority to Taiwanese Patent Application No. 103111982 filed on Mar. 31, 2014 in the Taiwan Intellectual Property Office, the contents of which are incorporated by reference herein.

### FIELD

The subject matter herein generally relates to a light guide member and an electronic device having the light guide member.

### BACKGROUND

An electronic device (e.g. a display device) able to be controlled remotely includes a cover, a fixing portion molded on the cover, a receiver to receive a remote control signal, and a supporting portion to support and fix the receiver. However, the fixing portion is directly molded on the cover and the cover is more vulnerable and easily damaged when the fixing portion is molded to it.

### BRIEF DESCRIPTION OF THE DRAWINGS

Implementations of the present technology will now be described, by way of example only, with reference to the attached figures.

FIG. 1 is a diagrammatic view of an electronic device according to the present disclosure.

FIG. 2 is an isometric view of part of the electronic device of FIG. 1.

FIG. 3 is an exploded view of the electronic device of FIG. 1 having a cover and a light guide member.

FIG. 4 is an isometric view of the cover of FIG. 3.

FIG. 5 is an isometric view of the light guide member of FIG. 3.

FIG. 6 is an assembled view of the electronic device of FIG. 1.

FIG. 7 is a cross sectional view of the electronic device along line VII-VII of FIG. 6.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

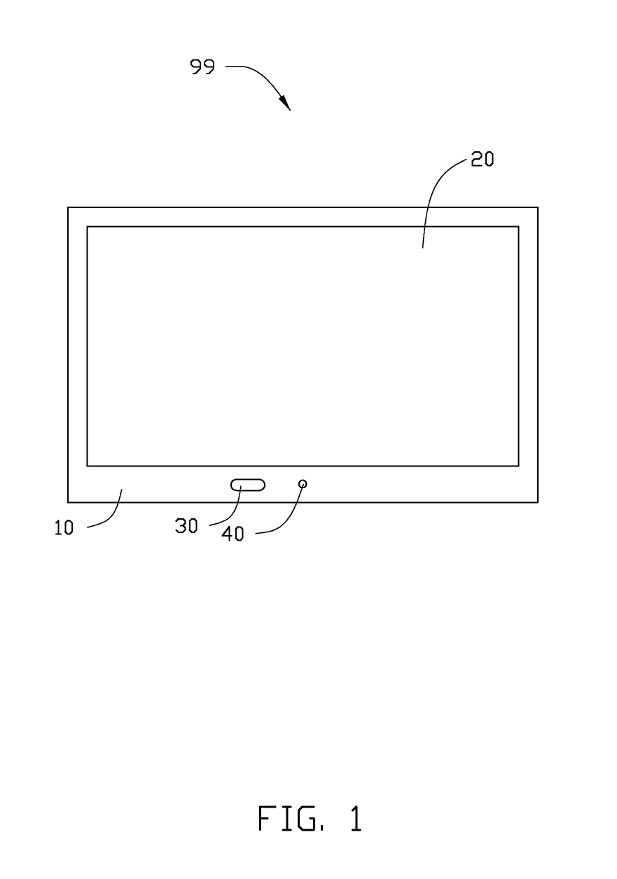

Referring to FIG. 1, an electronic device 99 can include a cover 10, a display panel 20, a light guide member 30, and an indicator 40. The cover 10 and the display panel 20 define a receiving space to receive the light guide member 30 and a receiver (not shown). The display panel 20 displays an image. The light guide member 30 is affixed to the cover 10 to receive and fix the receiver. The indicator 40 indicates a working state of the device of which it is part, that is, of the electronic device 99. The light guide member 30 receives a light signal from a remote controller and transmits the light signal to the receiver. In the embodiment, the indicator 40 can be a light emitting diode (LED) and the electronic device 99 can be a television.

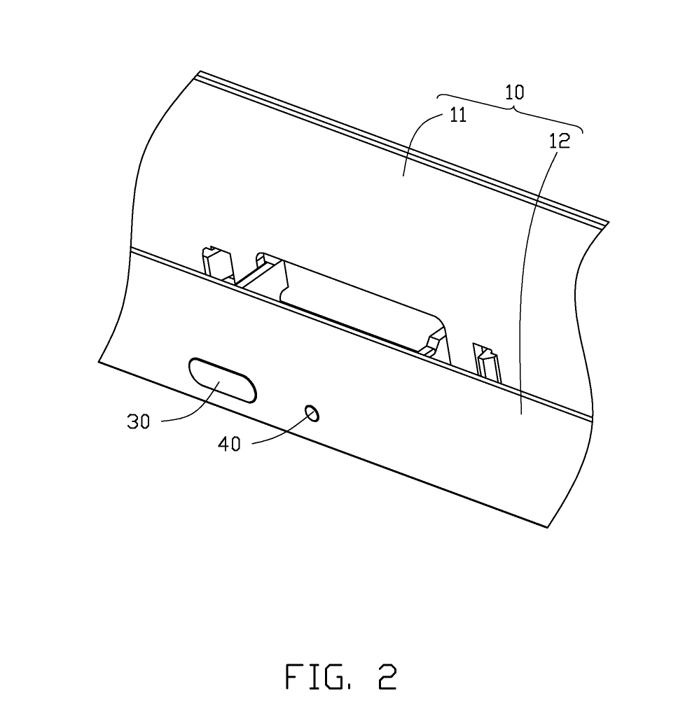

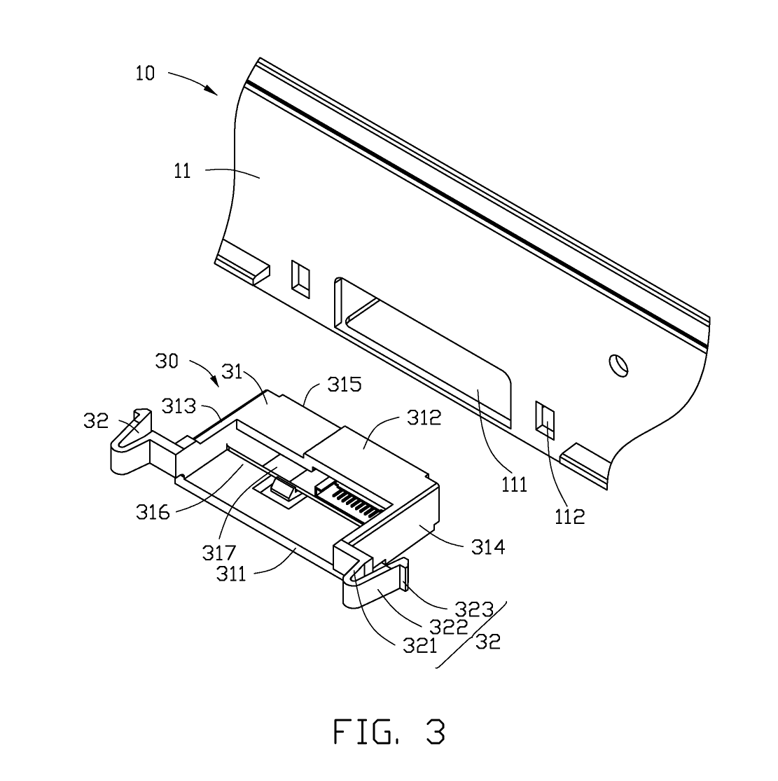

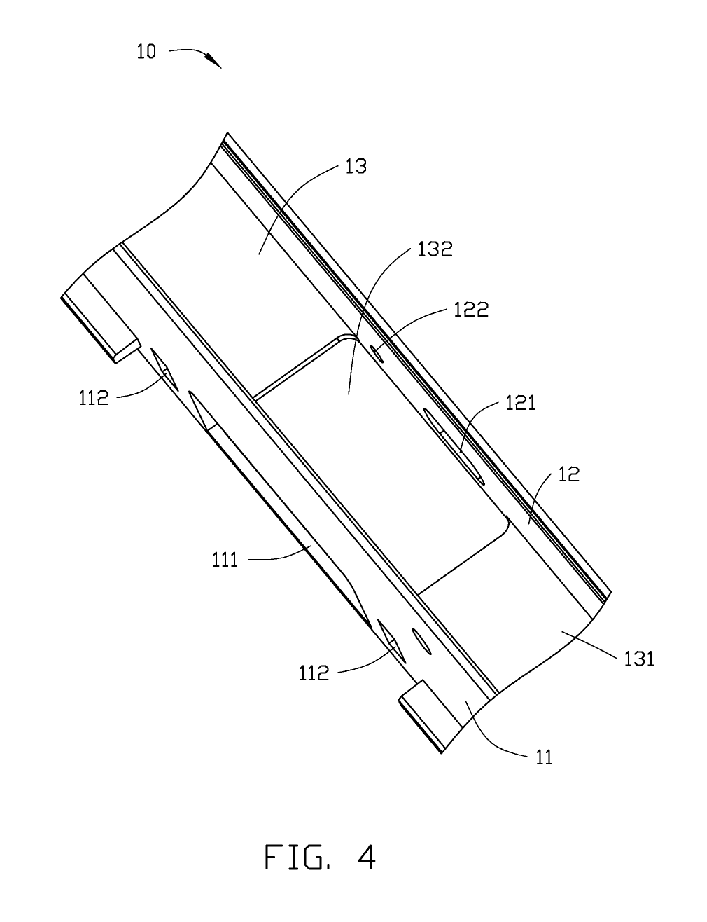

Referring to FIGS. 2-4, the cover 10 can include a first frame 11, a second frame 12, and a third frame 13. When the electronic device 99 is used by a user, the second frame 12 faces the user.

A first opening 111 and a first through hole 112 are defined on the first frame 11. In the embodiment, the first frame 11 can define two first through holes 112, the two first through holes 112 are defined on opposite sides of the first opening 111. In the embodiment, a shape of the first opening 111 can be a rectangle. A shape of the first through hole 112 can be a square.

The second frame 12 is parallel to the first frame 11. The second frame 12 can define a second opening 121 and a second through hole 122 facing the first opening 111. A size of the second opening 121 is smaller than a size of the first opening 111. The first opening 111 receives the light guide member 30. The second through hole 122 receives the indicator 40. In the embodiment, the second opening 121 and the second through hole 122 are defined on the second frame 12 near the third frame 13. A shape of the opening 121 can be an oval. A shape of the second through hole 122 can be a circle.

The third frame 13 connects the first frame 11 and the second frame 12. The third frame 13 can include a first surface 131. The third frame 13 defines a groove 132 corresponding to the first opening 111. A shape of the groove 132 can be a rectangle, a length of the groove 132 can be equal to a length of the first opening 111, and a width of the groove 132 can be equal to a width of the first surface 131.

The light guide member 30 can include a main body 31 and two fixing portions 32 arranged on opposite sides of the main body 31. A size of the main body 31 is smaller than a size of the first opening 111. The main body 31 can include a back plate 311 and a front plate 312, a first sidewall 313, a second sidewall 314, and a third sidewall 315. The first sidewall 313, the second sidewall 314, and the third sidewall 315 are arranged between the back plate 311 and the front plate 312. The first sidewall 313 is parallel to the second sidewall 314 and the third sidewall 315 is arranged between the first sidewall 313 and the second sidewall 314. The back plate 311, the front plate 312, the first sidewall 313, the second sidewall 314, and the third sidewall 315 define a receiving portion 316 to receive the receiver.

The receiver is affixed to a circuit board 317 to receive a light signal. In the embodiment, the circuit 317 is arranged on the back plate 311.

The two fixing members 32 are arranged on opposite sides of the main body 31 away from the third sidewall 315. Each fixing member 32 is V-shaped. One fixing member 32 is arranged on the first sidewall 313 and the other fixing member 32 is arranged on the second sidewall 314. Each fixing member 32 can include a connecting portion 321 and an inserting portion 322. The connecting portion 321 connects to one end of the second sidewall 314 away from the third sidewall 315. The inserting portion 322 can include a hook 323. A distance between the two inserting portions 322 is bigger than a distance between the two first through holes 112.

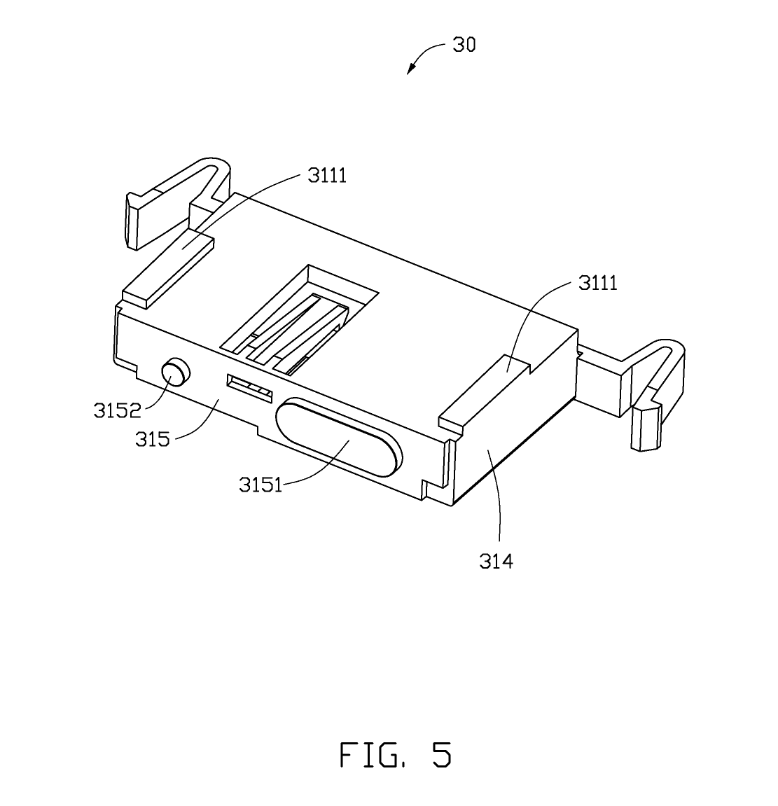

Referring to FIG. 5, two restriction blocks 3111 are arranged on the back plate 311 opposite to the receiving portion 316. One restriction block 3111 extends along the first sidewall 313, and the other restriction block 3111 extends along the second sidewall 314.

A first protrusion 3151 protrudes from the third sidewall 315 opposite to the receiving portion 316. The first protrusion 3151 latches in the second opening 121. A second protrusion 3152 protrudes from the third sidewall 315 opposite to the receiving portion 316. The second protrusion 3152 latches in the second through hole 122. A shape of the first protrusion 3151 is similar to that of the second opening 121, and a shape of the second protrusion 3152 is similar to that of the second through hole 122. In the embodiment, the first protrusion 3151 receives the receiver and the second protrusion 3152 receives the indicator 40.

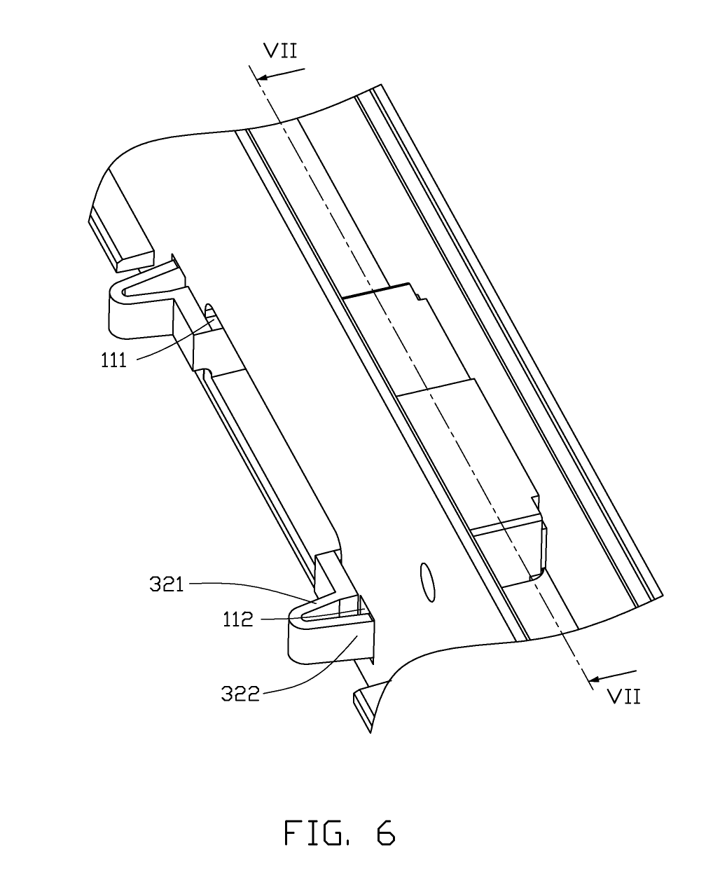

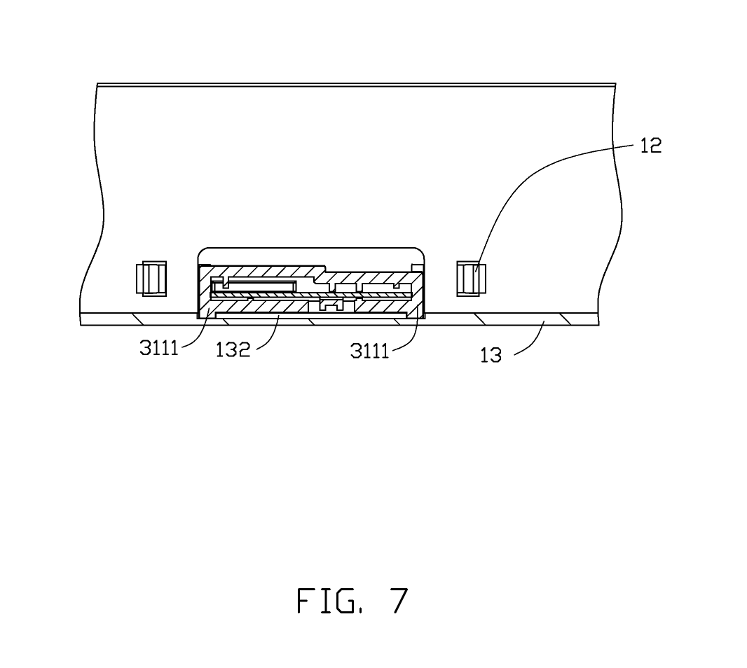

Referring also to FIGS. 6-7, when the electronic device 99 is assembled, the main body 31 is inserted into the first opening 111 and latches with the groove 132. The two restriction blocks 3111 resist the groove 132. The first protrusion 3151 latches in the second opening 121. The second protrusion 3152 latches in the second through hole 122. The two inserting portions 322 are inserted into the two first through holes 112. As the distance between the two inserting portions 322 is bigger than the distance between the two first through holes 112, and as each inserting portion 322 includes the hook 323, the two inserting portions 322 are fixed closely in the two first through holes 112.

In summary, the light guide member 30 is fixed closely on the cover 10 by the two inserting portions 322 and the location of the light guide member 30 does not render the cover 10 vulnerable to damage. Further, when the fixing member 32 is damaged, only the light guide member 30 will require to be replaced and not the cover 10 itself.

It is to be understood that even though numerous characteristics and advantages of the present embodiments have been set forth in the foregoing description, with details of the structures and functions of the embodiments, the disclosure is illustrative only; and changes may be in detail, especially in the matter of arrangement of parts within the principles of the embodiments to the full extent indicated by the broad general meaning of the terms in which the appended claims are expressed.

What is claimed is:

1. A electronic device, comprising:
a cover;
a display panel affixed to the cover;
a first through hole defined in the cover; and
a light guide member configured to receive a receiver, the light guide member comprising a main body and two fixing members arranged on opposite sides of the main body, the two fixing members configured to engage the first through hole to secure the light guide member to the cover.

2. The electronic device of claim 1, wherein the light guide member receives a light signal from a remote controller and transmits the light signal to the receiver.

3. The electronic device of claim 1, wherein each fixing member comprises a connecting portion and an inserting portion, the connecting portion connects the main body and the inserting portion, the inserting portion latches in the first through hole.

4. The electronic device of claim 3, wherein each fixing member is V-shaped, and the inserting portion comprises a hook to latches in the first through hole.

5. The electronic device of claim 1, wherein the cover defines a first opening and two first through holes, the two first through holes are defined on the opposite sides of the first opening; the main body is inserted into the first opening and the two fixing members latch with the two first through holes, respectively.

6. The electronic device of claim 5, wherein the cover comprises a first frame, a second frame, and a third frame; the second frame is parallel to the first frame, the first through hole and the first opening are defined in the first frame.

7. The electronic device of claim 6, wherein the third frame connects between the first frame and the second frame, the third frame defines a groove corresponding to the first opening; and the main body is inserted into the first opening and latches with the groove.

8. The electronic device of claim 7, wherein the main body comprises a back plate and a front plate, a first sidewall, a second sidewall, and a third sidewall, the first sidewall, the second sidewall, and the third sidewall are arranged between the back plate and the front plate, the first sidewall is parallel to the second sidewall; and the back plate, the front plate, the first sidewall, the second sidewall, and third sidewall define a receiving portion to receive the receiver.

9. The electronic device of claim 8, wherein two restriction blocks are arranged on the back plate opposite to the receiving portion, one restriction block extends along the first sidewall, and the other restriction block extends along the second sidewall, the two restriction blocks resist the groove.

10. The electronic device of claim 8, wherein the second frame defines a second opening and a second through hole facing to the first opening, a first protrusion protrudes from the third sidewall opposite to the receiving portion and latches in the second opening, and a second protrusion protrudes from the third sidewall opposite to the receiving portion and latches in the second through hole.

11. A light guide member of an electronic device, the electronic device comprising:
a cover and a display panel affixed to the cover;
a first through hole defined in the cover; and
the light guide member configured to affix and receive a receiver; wherein the light guide member comprises a main body and two fixing members arranged on opposite sides of the main body, the two fixing members configured to engage the first through hole to secure the light guide member to the cover.

12. The light guide member of claim 11, wherein the light guide member receives a light signal from a remote controller and transmits the light signal to the receiver.

13. The light guide member of claim 11, wherein each fixing member comprises a connecting portion and an inserting portion, the connecting portion connects between the main body and the inserting portion, the inserting portion latches in the first through hole.

14. The light guide member of claim 13, wherein each fixing member is V-shaped, and the inserting portion comprises a hook to latches in the first through hole.

15. The light guide member of claim 11, wherein the cover defines a first opening and two first through holes, the two first through holes are defined on the opposite sides of the first opening; the main body is inserted into the first opening and the two fixing members latch with the two first through holes, respectively.

16. The light guide member of claim 15, wherein the cover comprises a first frame, a second frame, and a third frame; the second frame is parallel to the first frame, the first through hole and the first opening are defined in the first frame.

17. The light guide member of claim 16, wherein the third frame connects between the first frame and the second frame, the third frame defines a groove corresponding to the first opening; and the main body is inserted into the first opening and latches with the groove.

18. The light guide member of claim 17, wherein the main body comprises a back plate and a front plate, a first sidewall, a second sidewall, and a third sidewall, the first sidewall, the second sidewall, and the third sidewall are arranged between the back plate and the front plate, the first sidewall is parallel to the second sidewall; and the back plate, the front plate, the first sidewall, the second sidewall, and third sidewall define a receiving portion to receive the receiver.

19. The light guide member of claim 18, wherein two restriction blocks are arranged on the back plate opposite to the receiving portion, one restriction block extends along the first sidewall, and the other restriction block extends along the second sidewall, the two restriction blocks resist the groove.

20. The light guide member of claim 18, wherein the second frame defines a second opening and a second through hole facing to the first opening, a first protrusion protrudes from the third sidewall opposite to the receiving portion and latches in the second opening, and a second protrusion protrudes from the third sidewall opposite to the receiving portion and latches in the second through hole.
